(19) United States
(12) Patent Application Publication
(10) Pub. No.: US 2012/0140427 A1
(43) Pub. Date: Jun. 7, 2012

(54) PRINTED CIRCUIT BOARD (PCB) ASSEMBLY WITH ADVANCED QUAD FLAT NO-LEAD (A-QFN) PACKAGE

(75) Inventors: Thomas Matthew GREGORICH, San Diego, CA (US); Chih-Tai Hsu, Hsinchu City (TW); Fu-Kang Pan, Xindian City (TW)

(73) Assignee: MEDIATEK INC., Hsin-Chu (TW)

(21) Appl. No.: 13/279,732

(22) Filed: Oct. 24, 2011

Related U.S. Application Data
(60) Provisional application No. 61/418,523, filed on Dec. 1, 2010.
(60) Provisional application No. 61/423,164, filed on Dec. 15, 2010.

(51) Int. Cl. H05K 7/10

(52) U.S. Cl. 361/767

(57) ABSTRACT

A printed circuit board assembly (PCB) assembly is provided, including a printed circuit board (PCB) comprising a plurality of conductive pads and an advanced quad pack no-lead chip (a-QFN) package soldered to the printed circuit board. In one embodiment, the conductive pads have a first surface area and the QFN package includes a plurality of leads facing the conductive pads, having a second surface area, wherein a ratio between the second surface area and the first surface area is about 20% to 85% to ensure a physical connection between the PCB and the a-QFN package.

### CROSS REFERENCE TO RELATED APPILCATIONS

This application claims the benefit of U.S. Provisional Application No. 61/418,523 filed on Dec. 1, 2010, and U.S. Provisional Application No. 61/423,164 filed on Dec. 15, 2010, the entirety of which are incorporated by reference herein.

### BACKGROUND OF THE INVENTION

1. Field of the Invention

The present invention relates to electronic assemblies, and more particular to printed circuit board (PCB) assemblies including an advanced quad flat no-lead (a-QFN) package attached to a PCB.

2. Description of the Related Art

The attachment of components to printed circuit boards (PCBs) produces printed circuit board assemblies (PCBAs), which can be used as motherboards in computers such as servers, as cards such as graphics cards, and for other purposes. A PCB is a laminated board made of an insulating material such as plastic which contains several layers of metal such as copper separated by insulating material. The metal may function to establish electrical connections between parts mounted on the board, conduct heat, or provide a ground.

One increasingly popular electronic component of PCBAs is an advanced quad flat no-lead (QFN) chip package. An a-QFN chip package is an electronic component encapsulated in plastic or some other insulating material. The a-QFN chip package contains multi rows of IO pads, which are areas in which bare metal is exposed, on each of its four sides (hence, the “quad” in a-QFN) for electrical connectivity with the PCB. An a-QFN chip package also typically contains a thermal pad thereunder, which is an exposed area of metal for conducting heat away from the package. An a-QFN chip package may be light, have a small footprint, and feature good thermal and electrical conductivity. The small footprint conserves space on the PCB, which can be scarce.

Note that due to the multi rows of IO pads in an a-QFN chip package, electrical connections between terminals thereof with bonding pads formed over a PCB, are critical for functionality of a subsequently formed PCB assembly.

### BRIEF SUMMARY OF THE INVENTION

Thus, a printed circuit board (PCB) assembly with improved attachment between a printed circuit board (PCB) and an advanced quad flat no-lead (a-QFN) package thereover is provided.

An exemplary PCB assembly comprises a printed circuit board (PCB) comprising a plurality of conductive pads, wherein the conductive pads have a first surface area, and an advanced quad pack no-lead chip (a-QFN) package soldered to the printed circuit board, wherein the QFN package comprises a plurality of leads facing the conductive pads, having a second surface area, wherein a ratio between the second surface area and the first surface area is about 20% to 85% to ensure physical connection between the PCB and the a-QFN package.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1-2 are cross sections of a process for forming a printed circuit board assembly comprising an advanced quad flat no-lead (a-QFN) package attached to a PCB according to an embodiment of the invention; and

FIG. 3 is schematic diagram showing a region 250 shown in FIG. 2;

FIGS. 4-5 are cross sections of a process for forming a printed circuit board assembly comprising an advanced quad flat no-lead (a-QFN) package attached to a PCB according to another embodiment of the invention; and

FIG. 6 is schematic diagram showing a region 250′ shown in FIG. 5;

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

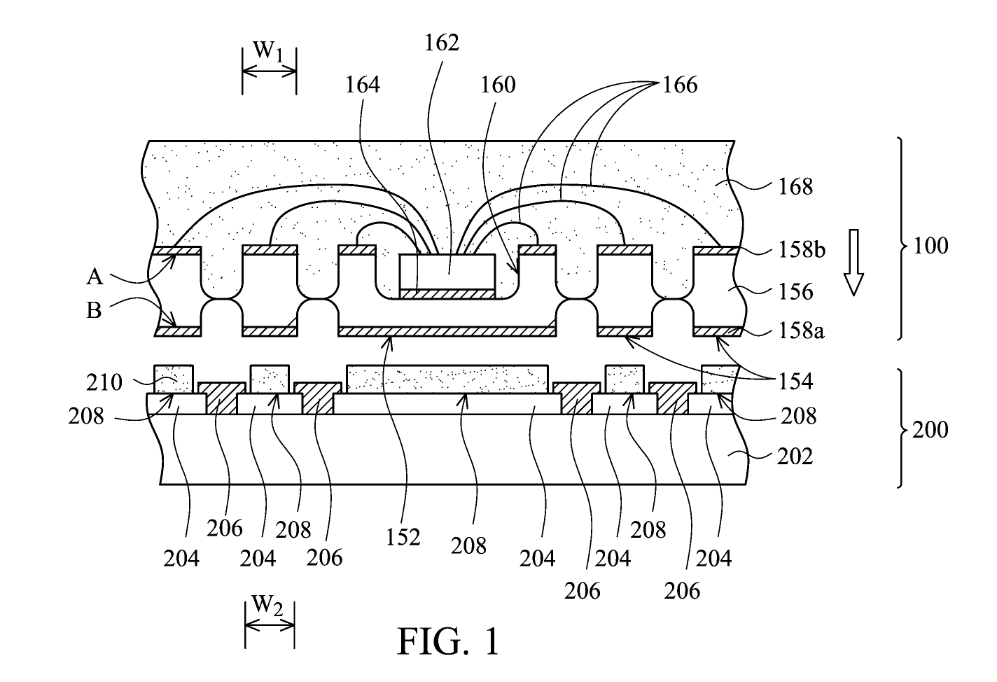

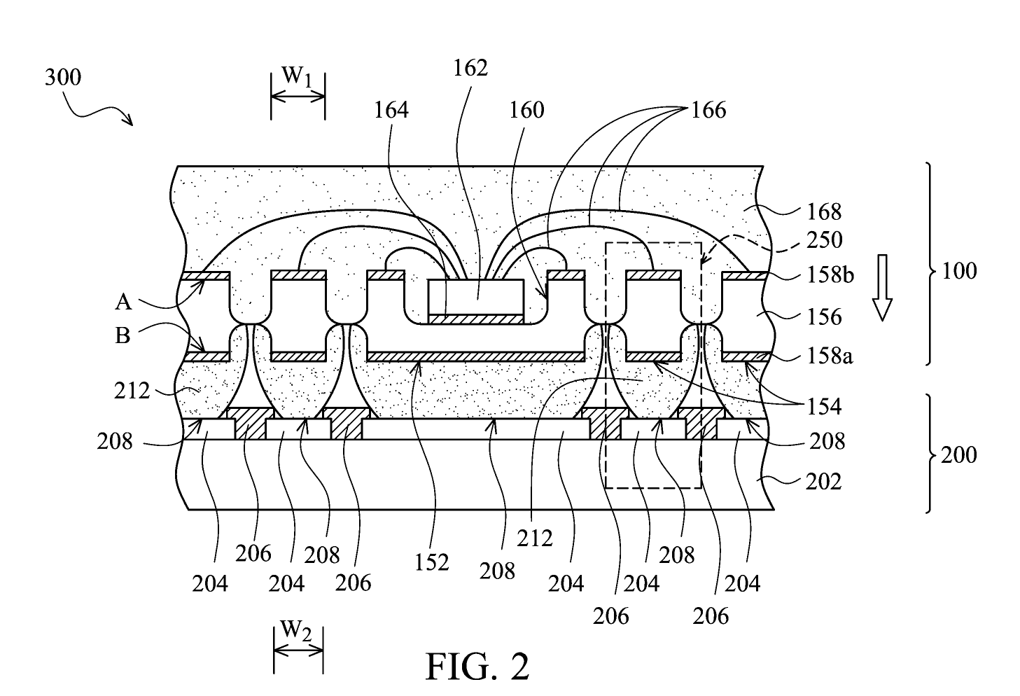

FIGS. 1-2 are cross sections of an exemplary process for forming a printed circuit board (PCB) assembly comprising an advanced quad flat no-lead (a-QFN) package attached to a PCB.

In FIG. 1, an advanced quad flat no-lead (a-QFN) package 100 and a printed circuit board (PCB) 200 are first provided. As shown in FIG. 1, the a-QFN package 100 comprises, for example, a carrier comprising a die pad 152 and a plurality of leads 154. The die pad 152 and the leads 154 are formed of a conductive substrate 156 with metal layers 158a and 158b formed on opposite surfaces A and B thereof. A cavity 160 is formed in the conductive substrate 156 of the die pad 152 to accommodate a chip 162. The chip 162 is mounted on the conductive substrate 156 of the die pad 152 within the cavity 160 by an adhesive layer 164, and the chip 162 is electrically connected with various metal layers 158b of the carrier 150 by a plurality of bonding wires 166. The metal layers 158b, the bonding wires 166, and the chip 162 are encapsulated by a molding compound 168.

Further, as shown in FIG. 1, the PCB 200 provided can be, for example, a solder mask defined (SMD) type PCB and may comprise a package substrate 202 with a plurality of conductive pads 204 formed thereon. A plurality of patterned solder masks 206 are formed over portions of the package substrate 202 and the conductive pads 204 to define bonding surfaces 208, which are top surfaces of a portion of the conductive pads 204 exposed by the patterned solder masks 206. A solder layer 210 is respectively provided over portions of each of the bonding surfaces 208 of the conductive pads 204. Portions of the leads 154 and the die pad 152 not encapsulated by the molding compound 168 face the PCB 200 and respectively align with one of the conductive pads 204. The leads 154 and the die pads 152 may have similar planar configurations, such as circular or rectangular configurations. For the purposes of ensuring physically connections between leads 154 and the conductive pads 204 opposite thereto, a terminal size of the metal layer 158a of the leads 154 is preferably smaller than a terminal size of a portion of the conductive pads 204 exposed by the patterned solder masks 206. In one embodiment, the metal layers 158a of the leads 154 may have a diameter/width W₁ and a planar surface area A1 (not shown), and the portion of the conductive pad 204 of the PCB 200 exposed by the patterned solder masks 206 is opposite to the lead 154 and may have a diameter/width W₂ and a planar surface area A2 (not shown). Therefore, a surface area ratio (A1/A2) between the terminal size of the metal layer 158a of the leads 154 and the portion of the conductive pad 208 exposed by the patterned solder masks 206 of the PCB 200 opposite to the leads 154 is about 20% to 85%, and preferably about 50%-80%.

Next, the a-QFN package 100 is moved toward the PCB 200 and is disposed thereover, and a reflow process (not shown) is then performed under an adequate temperature to transform the solder layers 210 into solder balls 212 to physically and electrically connect the leads 154 and the die pad 152 of the a-QFN package 100 with the conductive pads 204 of the PCB 200. After the reflow process, an exemplary printed circuit board (PCB) assembly 300 with ensured physically connections between leads 154 of the advanced quad flat no-lead (a-QFN) package 100 and the conductive pads 204 of the SMD type PCB 200 is obtained.

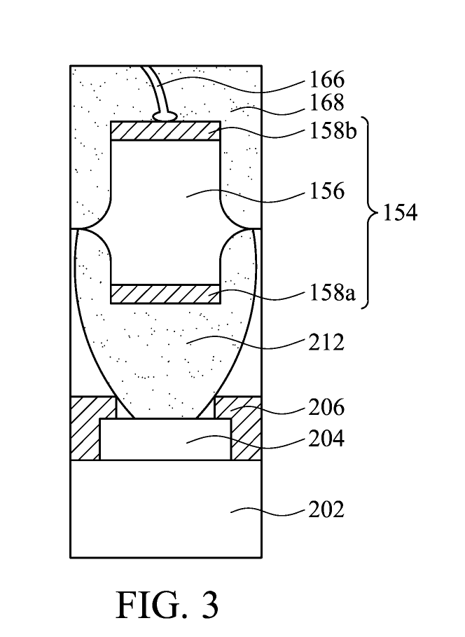

FIG. 3 is a schematic diagram of a region 250 shown in FIG. 2. As shown in FIG. 3, an enlarged view of a solder ball 212 connects to a lead 154 and a conducive pad 204. Since the terminal size of the metal layer 158a of the lead 154 is preferably smaller than the terminal size of the portion of the conductive pad 204 exposed by the patterned solder masks 206, thus, the solder ball 212 may physically surround the lead 154 not only from a bottom surface thereof but also from sidewall surfaces thereof, thereby ensuring physical connections between the lead 154 and the conducive pad 204.

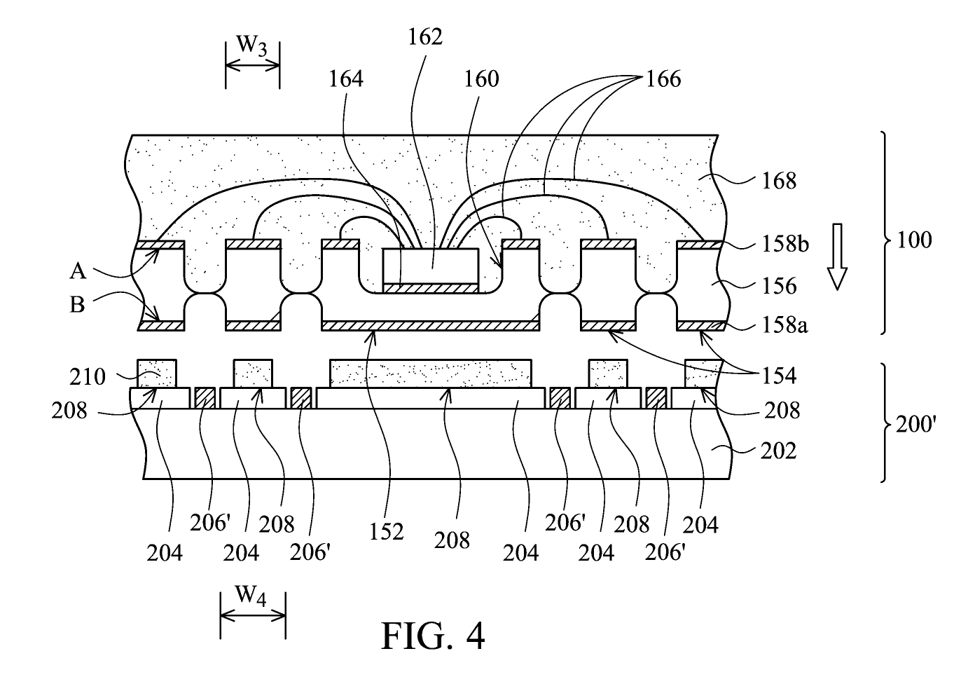

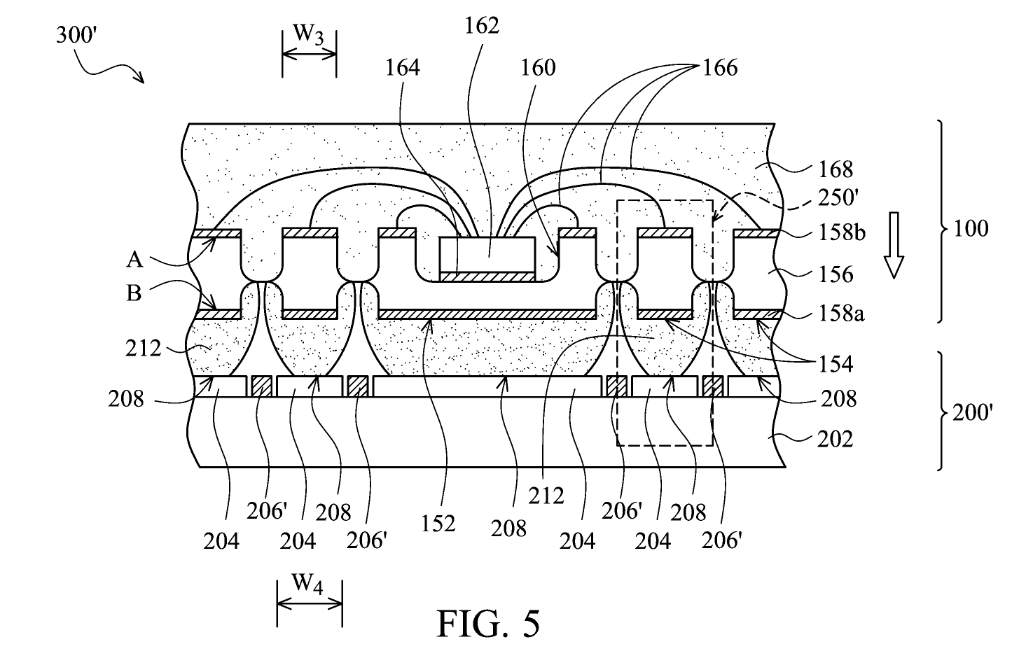

FIGS. 4-5 are cross sections of another exemplary process for forming a printed circuit board assembly comprising an advanced quad flat no-lead (a-QFN) package attached to a PCB.

In FIG. 4, the advanced quad flat no-lead (a-QFN) package 100 as shown in FIGS. 1-2 and a printed circuit board (PCB) 200′ are first provided. The a-QFN package 100 is formed with the same components shown in FIGS. 1-2 and is not described here again. As shown in FIG. 4, the printed circuit board (PCB) 200′ provided can be, for example, a non-solder mask defined (NSMD) type PCB and may comprise a package substrate 202 with a plurality of conductive pads 204 formed thereon, wherein the conductive pads 204 have an exposed bonding surface 208. A plurality of patterned solder masks 206′ are formed over portions of the substrate 202 and are spaced from the conductive pads 204. A solder layer 210 is respectively provided over portions of each of the bonding surfaces 208 of the conductive pads 204. Portions of the leads 154 and the die pad 152 not encapsulated by the molding compound 168 face the PCB 200′ and respectively align with one of the conductive pads 204. The leads 154 and the die pads 152 may have similar planar configurations, such as circular or rectangular configurations.

For the purpose of ensuring physical connections between leads 154 and the conductive pads 204 opposite thereto, a terminal size of the metal layer 158a of the leads 154 is preferably smaller than a terminal size of the conductive pads 204. In one embodiment, the metal layers 158a of the leads 154 may have a diameter/width W₃ and a planar surface area A3 (not shown), and the conductive pad 208 of the PCB 200 opposite to the lead 154 may have a diameter/width W₄ and a planar surface area A4 (not shown) of. Therefore, a surface area ratio (A3/A4) between the terminal size of the metal layer 158a of the leads 154 and the conductive pad 208 of the PCB 200′ opposite to the leads 154 is about 20% to 85%, and preferably about 50%-80%.

Next, the a-QFN package 100 is moved toward the PCB 200′ and is disposed thereover, and a reflow process (not shown) is then performed under an adequate temperature to transform the solder layers 210 into solder balls 212 to physically and electrically connect the leads 154 and the die pad 152 of the a-QFN package 100 with the conductive pads 204 of the PCB 200′. After the reflow process, an exemplary a printed circuit board (PCB) assembly 300′ with ensured physical connections between leads 154 of the advanced quad flat no-lead (a-QFN) package 100 and the conductive pads 204 of the NSMD type PCB 200′ is obtained.

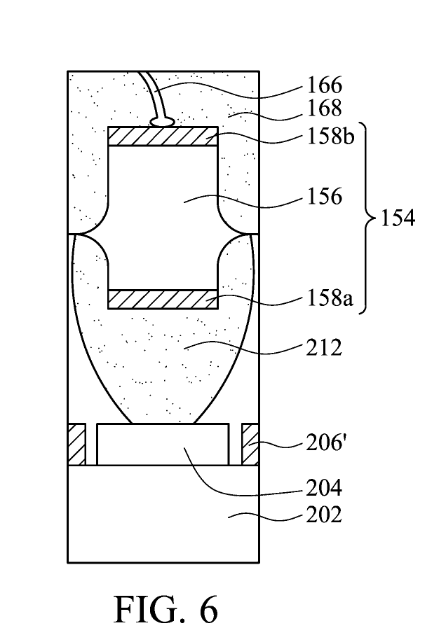

FIG. 6 is a schematic diagram of a region 250′ shown in FIG. 3. As shown in FIG. 6, an enlarged view of a solder ball 212 connects to a lead 154 and a conducive pad 204. Since a terminal size of the metal layer 158a of the lead 154 is preferably smaller than a terminal size of the conductive pad 204, thus, the solder ball 212 may physically surround the lead 154 not only from a bottom surface thereof but also from sidewall surfaces thereof, thereby ensuring physical connections between the lead 154 and the conducive pad 204.

In the embodiments shown in FIGS. 1-6, the conductive substrate 156 of the a-QFN package 100 may comprise materials such as copper, a copper alloy, or other applicable metal materials. The metal layers 158a and 158b can be, for example, a gold/nickel stacked layer. The package substrate 202 of the PCB 200/200′ may comprise materials such as glass-fiber-reinforced epoxy (FR4).

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A printed circuit board assembly (PCBA), comprising:
a printed circuit board (PCB) comprising a plurality of conductive pads, wherein the conductive pads have a first surface area; and
an advanced quad pack no-lead chip (a-QFN) package soldered to the printed circuit board, wherein the QFN package comprises a plurality of leads facing the conductive pads, having a second surface area, wherein a ratio between the second surface area and the first surface area is about 20% to 85% to ensure a physical connection between the PCB and the a-QFN package.

2. The PCBA of claim 1, wherein the ratio between the second surface area and the first surface area is about 50% to 80%.

3. The PCBA of claim 1, wherein the PCB is a solder mask defined type PCB and the first surface area of the conductive pads is a surface area thereof exposed by the solder mask.

4. The PCBA of claim 1, wherein the PCB is a non-solder mask defined type PCB.

5. The PCBA of claim 1, wherein the a-QFN package is soldered to the PCB by solder balls, and the solder balls physically surround a bottom surface and sidewall surfaces of the leads of the a-QFN package.

6. The PCBA of claim 1, wherein the a-QFN package further comprises a chip and the chip is connected with the leads by bonding wires.

7. The PCBA of claim 6, wherein the a-QFN package further comprises a molding compound encapsulating the chip, the bonding wires and portions of the leads.
